(19) United States
(12) Patent Application Publication
(10) Pub. No.: US 2026/0114283 A1
(43) Pub. Date: Apr. 23, 2026

(54) ELECTRONIC DEVICE WITH A METAL SCREEN FOR REDUCING THE SPACE CHARGE EFFECT, AND MANUFACTURING METHOD THEREOF

(71) Applicant: STMicroelectronics International N.V., Geneva (CH)

(72) Inventor: Vincenzo PALUMBO, Milano (IT)

(73) Assignee: STMicroelectronics International N.V., Geneva (CH)

(21) Appl. No.: 19/357,808

(22) Filed: Oct. 14, 2025

(30) Foreign Application Priority Data
Oct. 18, 2024 (IT) 102024000023214

(51) Int. Cl. H01L 23/00; H01L 23/538; H01L 23/58

(52) U.S. Cl. CPC H10W 42/00; H10W 70/60; H10W 70/611

(57) ABSTRACT

A semiconductor die includes a semiconductor substrate and a dielectric layer extending on the semiconductor substrate. A high-voltage module extends on the semiconductor substrate. A metal guard ring extends into the dielectric layer and completely surrounds the high-voltage module. The die further includes at least one electronic device extending externally to the guard ring. A metal capping layer includes: a first portion extending over the high-voltage module and a second portion extending over the metal guard ring and in electrical contact with the metal guard ring. A bonding wire is electrically coupled to the first portion and extends over the dielectric layer at the electronic device. A metal screen extends above the guard ring, interposed between the bonding wire and the electronic device, in physical and electrical continuity with the second portion of the metal capping layer.

### PRIORITY CLAIM

This application claims the priority benefit of Italian Application for Patent No. 102024000023214 filed on Oct. 18, 2024, the content of which is hereby incorporated by reference in its entirety to the maximum extent allowable by law.

### TECHNICAL FIELD

The present invention relates to an electronic device and a manufacturing method thereof and, in particular, to an electronic device including a screen for reducing the space charge effect.

### BACKGROUND

In the semiconductor industry, high voltage (HV) and galvanically isolated integrated circuits are provided as Systems in Package (SiP), with a plurality of integrated circuit dice electrically connected to each other by bonding wires and fixed on respective frames that are electrically isolated.

Circuit elements of the dice may be biased, in use, to high voltages (for example, to voltages comprised between 100 V and 1700 V), by means of bonding wires. Typically, the bonding wires extend from the biased element towards the external environment, passing above, and partly facing, the respective die. These biasing voltages are different from the voltage value (e.g., ground value or comprised between 0 V and 100 V) at which the surface of the respective dice facing the respective bonding wire is biased.

The voltage difference between a bonding wire and the surface of the underlying die generates an electric field having a high value inside the surface layers of the die. This electric field generates a problem known as the “space charge effect”. The space charge effect consists in the accumulation of electric charges in a limited region of material. These accumulated electric charges in turn generate an electric field that affects the operation of electronic devices integrated into the respective die and located in the vicinity of the region of accumulation of electric charges. In particular, MOS transistors located in a zone of the die underlying a bonding wire, or in proximity to a bonding wire, undergo a modification in their turn-on threshold voltage due to the space charge effect.

Furthermore, High Ohmic Polycrystalline resistors (“HIPO resistors”) located in a zone of the die underlying a bonding wire, or in proximity to a bonding wire, undergo a variation in resistance values due to the space charge effect.

Similarly, bipolar transistors may undergo a gain drift.

Furthermore, the space charge effect may also cause the formation of parasitic MOS transistors.

These issues particularly affect the operation of analog circuit blocks such as differential amplifiers and current mirrors.

FIG. 1A schematically illustrates a die 1, in a triaxial system of axes x, y, z orthogonal to each other, in a lateral sectional view on the xz plane.

The die 1 includes a solid body 2, which in turn comprises a substrate 4 made of semiconductor material such as, for example, silicon (Si), or silicon carbide (SiC), or gallium nitride (GaN), or of the SOI (Silicon On Insulator) type; a dielectric layer 6 extending on a face 4a of the substrate 4 and a passivation layer 8 that extends over the dielectric layer 6, in particular in direct physical contact with a surface 6a of the dielectric layer 6.

The dielectric layer 6 is, for example, of silicon oxide (SiO₂). A first metal plate 10 extends inside the dielectric layer 6, at a distance from the surface 4a of the substrate 4; a second metal plate 12 extends into the dielectric layer 6, above the first metal plate 10 and at a distance from the first metal plate 10. The first metal plate 10 and the second metal plate 12 are, for example, made of copper (Cu) and form, as a whole, a capacitor 14 adapted to operate as a galvanic insulator.

Furthermore, a guard ring 16 extends inside the dielectric layer 6 and completely surrounds, in a top-plan view on the xy plane, the capacitor 14. The guard ring 16 includes a plurality of metal layers 18(1)-18(N) extending parallel to the xy plane at respective metal levels M(1)-M(N), electrically connected to each other and to the substrate 4 through metal through vias 20. The metal level M(1) corresponds to the metal level more proximate, or closest, to the surface 4a of the substrate 4, and the metal level M(N) corresponds to the metal level farthest from the surface 4a of the substrate 4; the intermediate metal levels M(2)-M(N−1) extend between the metal level M(1) and the metal level M(N) in progressive order moving away from the surface 4a of the substrate 4 along the direction of the z axis. The number N of metal levels depends on the architecture of the integrated circuit provided as SiP, and is comprised, for example, between 2 and 10, for example equal to 5.

Therefore, the metal layer 18(1) is a bottom metal layer having the minimum distance from the surface 4a of the substrate 4 with respect to the other metal layers 18(2)-18(N), and the metal layer 18(N) is a top metal layer having the greatest distance from the surface 4a of the substrate 4 with respect to the other metal layers 18(1)-18(N−1).

The guard ring 16 is coupled to a GND reference potential through the substrate 4.

Further metal layers 19(1)-19(N), in particular made of copper, are adapted to form electrical interconnections between different portions of the die 1, and also extend at the metal levels M(1)-M(N) that accommodate the metal layers 18(1)-18(N).

The first metal plate 10 and the second metal plate 12 of the capacitor 14 extend in respective metal levels M(1)-M(N). For example, the first metal plate 10 extends at a metal level between M(1) and M(N−1), for example the metal level M(4) in FIG. 1A, and the second plate 12 extends at the last metal level M(N).

Furthermore, a metal capping layer 24 extends into the dielectric layer 6 over the metal layer 18(N) and over the second plate 12, in direct electrical contact with the metal layer 18(N) and with the second plate 12. In particular, a portion 26 of the capping layer 24, which extends in electrical contact with the second plate 12, has a surface 26a at least partly exposed through an opening in the surface 6a of the dielectric layer 6 and a through hole in the passivation layer 8. Furthermore, a portion 28 of the capping layer 24, which extends in electrical contact with the guard ring 16 at the metal layer 18(N), has a surface 28a at least partly exposed through a respective opening in the surface 6a of the dielectric layer 6 and a through hole in the passivation layer 8.

The capping layer 24 provides surfaces 26a, 28a adapted to couple with external bonding wires, and also protects the metal layer 18(N) and the second plate 12 from external agents such as humidity or contaminations. The capping layer 24 is, for example, made of aluminum (Al).

The die 1 also includes a plurality of semiconductor devices 22 (only schematically illustrated in FIG. 1A), such as for example MOS transistors, bipolar transistors and/or polycrystalline resistors, extending into the substrate 4 at the surface 4a, and externally to the guard ring 16. The guard ring 16 is adapted to protect the plurality of semiconductor devices 22 from the high biasing voltages applied to the capacitor 14.

A bonding wire 30 extends over a portion of the die 1, at a distance from the passivation layer 8, terminating with one end thereof in electrical contact with the surface 26a of the portion 26 of the capping layer 24. In use, by means of the bonding wire 30, a biasing voltage may be applied to the second plate 12 of the capacitor 14 or a further die 200 may be connected to the die 100 (see FIG. 4), for example for applications that require an isolation between input and output, in particular in isolated gate drivers or isolated UARTs.

A voltage difference between the bonding wire 30 and the substrate 4 of the die 1 (where the bonding wire 30 faces the die 1) causes an accumulation of electric charges in a charge accumulation region 32 that extends partly inside the dielectric layer 6 and partly inside the passivation layer 8. The performance of the semiconductor devices 22 that extend at the charge accumulation region 32 are therefore degraded due to the accumulated space charge.

A solution to the space charge problem is illustrated in FIG. 1B.

FIG. 1B schematically illustrates a die 1′ in a triaxial system of axes x, y, z orthogonal to each other, in a lateral sectional view on the xz plane. In FIG. 1B, elements of the die 1′ in common with the die 1 of FIG. 1A are indicated with the same reference numbers and are not further described.

The die 1′ includes a metal screen 34, extending into the dielectric layer 6, laterally to the guard ring 16, in direct physical and electrical contact with the guard ring 16. The metal screen 34 is therefore coupled with the reference potential GND. The metal screen 34 is, in particular, an extension of a metal layer 18(1)-18(N). In the example illustrated in FIG. 1B the metal screen 34 is a lateral extension of the metal layer 18(N).

The metal screen 34 extends such as to be interposed between the semiconductor devices 22 and the bonding wire 30. Furthermore, the metal screen 34 confines the charges accumulated by space charge effect in a region 32′ that extends partly in the dielectric layer 6 and partly in the passivation layer 8, over the metal screen 34. In this manner, the electric field at the semiconductor devices 22 is reduced and the metal screen 34 protects the semiconductor devices 22a from the space charge effect.

However, the metal screen 34 occupies a portion of the respective metal level M(1)-M(N) that cannot be used to provide further electrical interconnections. Therefore, due to the presence of the metal screen 34, to provide such electrical interconnections a larger area occupancy or the addition of a further metal level M(N+1) is necessary. Both these solutions complicate the manufacturing process and increase the production costs of the final device.

A need is therefore felt for providing an electronic device and a manufacturing method thereof such as to overcome the drawbacks of the prior art.

### SUMMARY

In an embodiment, a semiconductor die comprises: a semiconductor substrate having a first surface; a dielectric layer extending on the first surface and having a second surface opposite to the first surface along an axis; a high-voltage module extending on the semiconductor substrate at least partly into the dielectric layer; a metal guard ring extending into the dielectric layer to completely surround the high-voltage module, wherein the metal guard ring is configured to be electrically coupled, in use, to a reference potential; at least one electronic device extending at the first surface externally to the guard ring; a metal capping layer including: a first portion extending over the high-voltage module and in electrical contact with the high-voltage module; and a second portion, electrically isolated from the first portion, extending over the metal guard ring and in electrical contact with the metal guard ring; a bonding wire electrically coupled to the first portion of the metal capping layer, and extending over the dielectric layer at said electronic device; a plurality of metal levels in the dielectric layer, each metal level including at least one respective first metal path for routing electrical signals and at least one respective second metal path forming a portion of the guard ring; and a screen of metal material above the guard ring, interposed between the bonding wire and the electronic device, in physical and electrical continuity with the second portion of the metal capping layer.

In an embodiment, a system comprises: the semiconductor die according to above; and a further semiconductor die, wherein said bonding wire connects the further semiconductor die to the first portion of the semiconductor die.

In an embodiment, a method of manufacturing a semiconductor die comprises the steps of: forming a dielectric layer on a first surface of a semiconductor substrate accommodating at least one electronic device at the first surface, said dielectric layer having a second surface opposite to the first surface along an axis; forming a high-voltage module at least partly in the dielectric layer; forming a metal guard ring in the dielectric layer, completely surrounding the high-voltage module, and configured to be electrically coupled, in use, to a reference potential, said electronic device being external to said metal guard ring; forming a metal capping layer including: forming a first portion over the high-voltage module and in electrical contact with the high-voltage module; and forming a second portion, electrically isolated from the first portion, over the metal guard ring and in electrical contact with the metal guard ring; forming a bonding wire electrically coupled to the first portion of the metal capping layer, and extending over the dielectric layer at said electronic device; and forming a screen of metal material above the guard ring, interposed between the bonding wire and the electronic device, in physical and electrical continuity with the second portion of the metal capping layer

### BRIEF DESCRIPTION OF THE DRAWINGS

For a better understanding of the present invention, some embodiments thereof are now described, purely by way of non-limiting example, with reference to the attached drawings, wherein:

FIG. 1A illustrates, in a lateral sectional view, a die of an integrated circuit;

FIG. 1B illustrates, in a lateral sectional view, a die of an integrated circuit;

FIG. 2 illustrates, in a lateral sectional view, a die of an integrated circuit;

FIGS. 3A-3E illustrate, in a lateral sectional view, manufacturing steps of the die of the integrated circuit of FIG. 2;

FIG. 4 schematically illustrates, in a perspective view, a system comprising a die of an integrated circuit.

### DETAILED DESCRIPTION

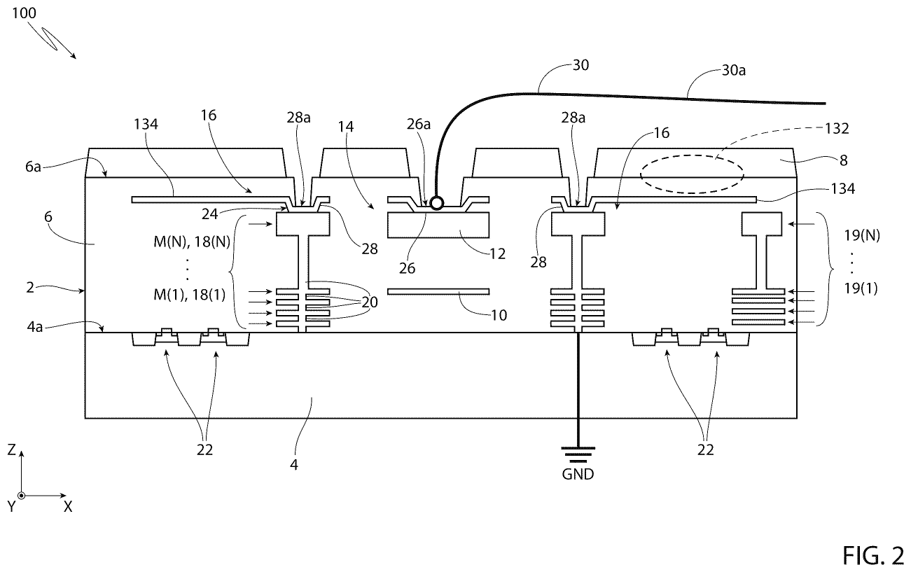

FIG. 2 schematically illustrates a die 100, according to an embodiment, in a triaxial system of axes x, y, z orthogonal to each other, in a lateral sectional view on the xz plane.

Elements of the die 100 in common with the die 1 are identified with the same reference numbers and are not further described.

The die 100 therefore includes the solid body 2, comprising in turn the substrate 4; the dielectric layer 6 on the surface 4a of the substrate 4, and the passivation layer 8 which extends in contact with the surface 6a of the dielectric layer 6.

The passivation layer 8 is, for example, made of silicon oxide (SiO₂), or silicon nitride (Si₃N₄), or silicon oxynitride (SiON), and/or polymeric materials such as polyimides or polyamides and has a thickness comprised between 1 μm and 20 μm, in particular equal to 15 μm.

The dielectric layer 6 is, for example, made of silicon oxide (SiO₂) or silicon oxynitride (SiON) or silicon nitride (Si₃N₄). In one embodiment, the dielectric layer 6 is a stack of layers of a single dielectric material such as silicon oxide (SiO₂) or silicon oxynitride (SiON) or silicon nitride (Si₃N₄). In another embodiment, the dielectric layer 6 comprises a stack of layers of different dielectric materials, such as, for example, silicon oxide (SiO₂), silicon oxynitride (SiON) or silicon nitride (Si₃N₄).

The dielectric layer 6 has a thickness comprised between 5 μm and 20μm, in particular equal to 14 μm.

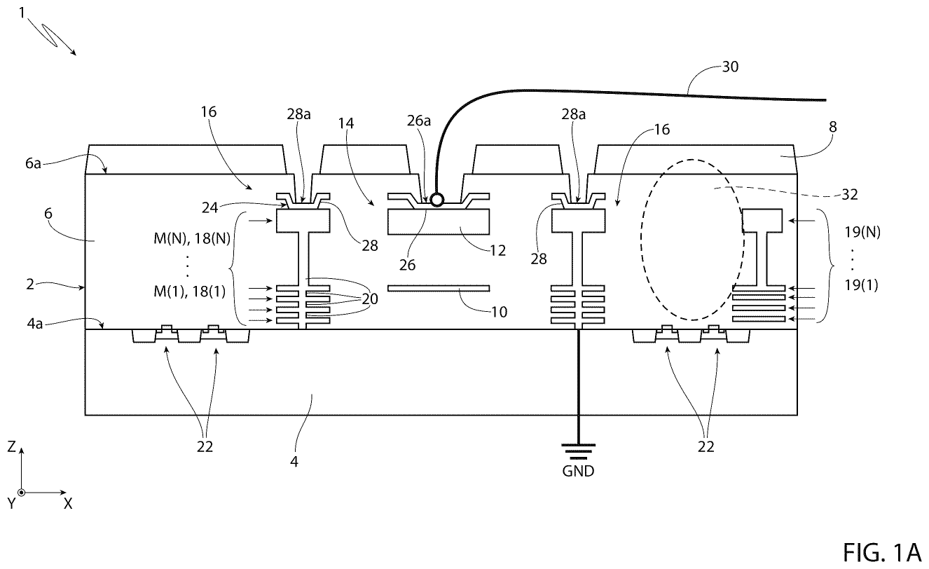

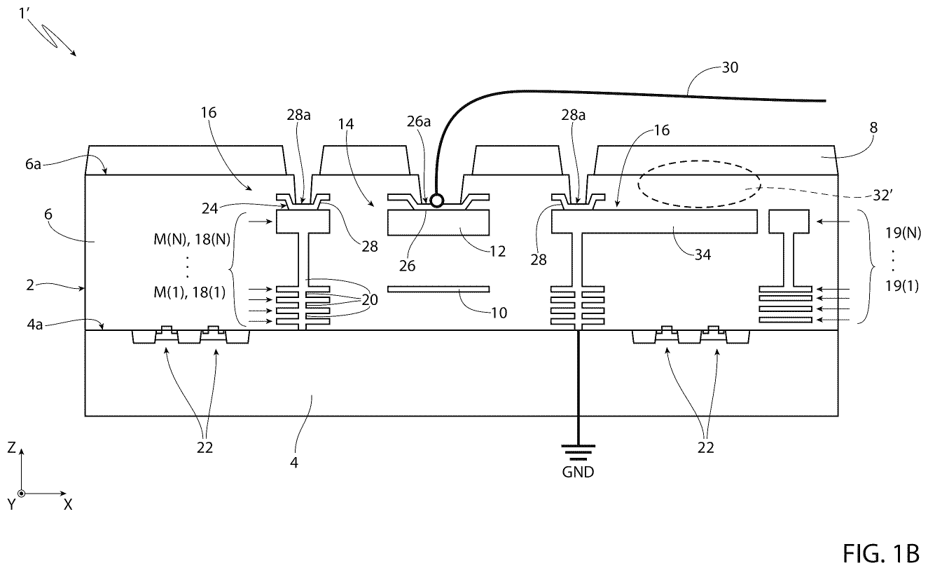

In one embodiment, common with the description of FIG. 1A, the first metal plate 10 and the second metal plate 12 form a capacitor 14 adapted to operate as a galvanic insulator. In another embodiment (not illustrated), the capacitor 14 may be replaced with, or arranged side by side to, a different high-voltage module 14, for example one or more electronic devices adapted to be biased to high voltage, such as high-voltage inductors or transistors. In respective embodiments, the high-voltage module 14 comprises one or more of: a capacitor, an inductor, a transistor, or a resistor.

The dielectric layer 6 also accommodates the guard ring 16 which completely surrounds, in a top-plan view on the xy plane, the capacitor 14. In the embodiment wherein the capacitor 14 is replaced with, or arranged side by side to, said one or more electronic devices adapted to be biased to high voltage, the guard ring 16 completely surrounds such one or more electronic devices.

In one embodiment, the guard ring 16 has, in a top-plan view on the xy plane, a substantially circular shape. Alternatively, the guard ring 16 may have an oval shape, or a shape that is generally polygonal or polygonal with rounded edges.

The dielectric layer 6 accommodates the capping layer 24, of metal material, which extends over the top metal layer 18(N) and the second plate 12, in electrical contact with the top metal layer 18(N) and with the second plate 12.

The capping layer 24 does not have a routing or electrical interconnection function, but is adapted to protect the top metal layer 18(N) from contaminations (such as, for example, humidity or corrosive agents) and to provide surfaces 26a, 28a suitable for being coupled with one or more bonding wires through soldering/wire bonding. The capping layer 24 is made of metal material, for example aluminum (Al) or a metal material comprising aluminum in a content (or tenor) greater than or equal to 90%.

In one embodiment, such metal material of the capping layer 24 is substantially aluminum. “Substantially” means aluminum except for potential impurity elements, for example due to intrinsic impurities of the raw material and/or impurities introduced by the processing of the raw material.

In one embodiment, the metal material of the capping layer 24 comprises an aluminum-copper alloy (AlCu), comprising a content (or tenor) of aluminum greater than or equal to 95%, preferably greater than or equal to 97%, more preferably greater than or equal to 99%, and a content (or tenor) of copper lower than or equal to 5%, preferably lower than or equal to 3%, more preferably lower than or equal to 1%.

The capping layer 24 has a thickness comprised between 0.5 μm and 3 μm, for example equal to 1.2 μm.

The die 100 also includes the plurality of semiconductor devices 22, common with the description of FIG. 1A, extending into the substrate 4 at the surface 4a, and externally to the guard ring 16.

In one embodiment, the bonding wire 30 is present, described also with reference to FIG. 1A. In particular, a portion 30a of the bonding wire 30 extends at a distance from the passivation layer 8, at least partly above the semiconductor devices 22. The bonding wire 30 is, for example, made of aluminum (Al), or gold (Au), or silver (Ag) or copper (Cu). By way of example, the bonding wire 30 has a section having a diameter comprised between 20 μm and 50 μm.

The die 100 also includes a screen 134, in particular a metal screen 134. In one embodiment, the metal screen 134 comprises aluminum in a content (or tenor) greater than or equal to 90%. In one embodiment, the screen 134 is formed by patterning the capping layer 24, and extends parallel to the xy plane in the dielectric layer 6, laterally and externally to the guard ring 16. In particular, the metal screen 134 is interposed between the semiconductor devices 22 and the bonding wire 30, and is in electrical contact with the portion 28. Even more in particular, the metal screen 134 is vertically interposed (i.e., interposed along the z axis) between the semiconductor devices 22 and the bonding wire 30, and is in physical and electrical continuity with the portion 28. In particular, the metal screen 134 extends as a continuation of the portion 28 of the capping layer 24. More in particular, the metal screen 134 and the portion 28 of the capping layer 24 are a single piece (monolithic).

The metal screen 134 extends inside the dielectric layer 6. In one embodiment, the metal screen 134 extends, in a top-plan view on the xy plane, completely surrounding the guard ring 16.

In another embodiment, the metal screen 134 extends, in a top-plan view on the xy plane, partly surrounding the guard ring 16, but still extending above the semiconductor devices 22, between the bonding wire 30 and the semiconductor devices 22.

The metal screen 134 is electrically coupled with the guard ring 16 through the portion 28, and is therefore biased, in use, to the reference potential GND.

In particular, the metal screen 134 is made of the same material as the capping layer 24, and in particular the portion 28.

In a preferred embodiment, the metal screen 134 is made of aluminum (Al) or an aluminum-copper alloy (AlCu) or an alloy including aluminum, while the metal layers 18(1)-18(N) are made of copper (Cu) or substantially copper.

A high voltage difference (for example in the range 100 V-1700 V) between the bonding wire 30 and the substrate 4 of the die 100 may cause an accumulation of electric charges in a charge accumulation region 132, extending above the metal screen 134, partly inside the dielectric layer 6 and partly inside the passivation layer 8, at the bonding wire 30. In other words, the metal screen 134 confines the charges accumulated by space charge effect in the charge accumulation region 132. In this manner, the electric field generated by the charges accumulated by space charge effect in the charge accumulation region 132, at the semiconductor devices 22, is reduced or screened; therefore, the metal screen 134 protects the semiconductor devices 22 from the space charge effect.

The metal screen 134 allows the semiconductor devices 22 to be protected from the space charge effect without using portions of metal layers 18(1)-18(N) (as instead occurs in the embodiment of FIG. 1B), thus providing a saving in terms of area occupancy and avoiding the need to use additional metal levels, reducing the complexity and cost of the manufacturing process of the die 100.

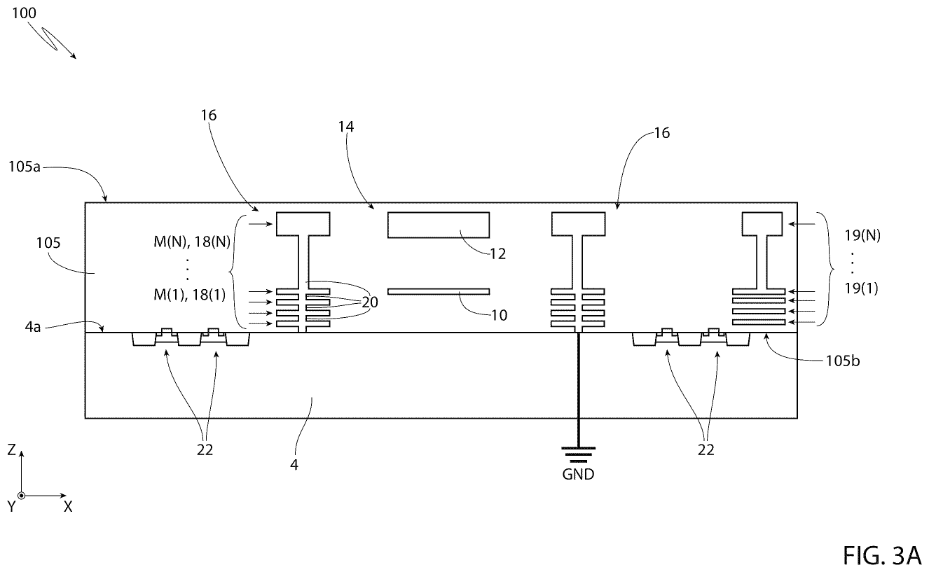

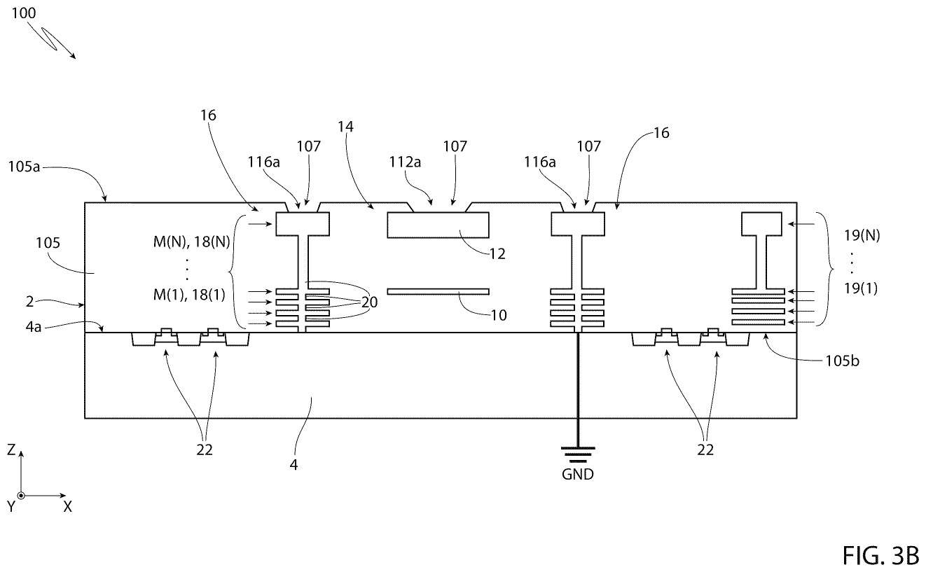

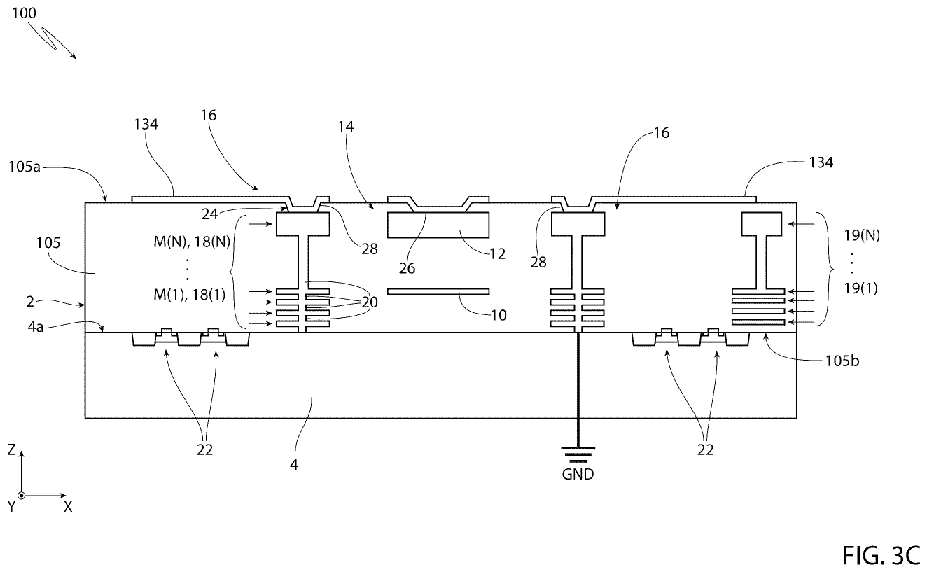

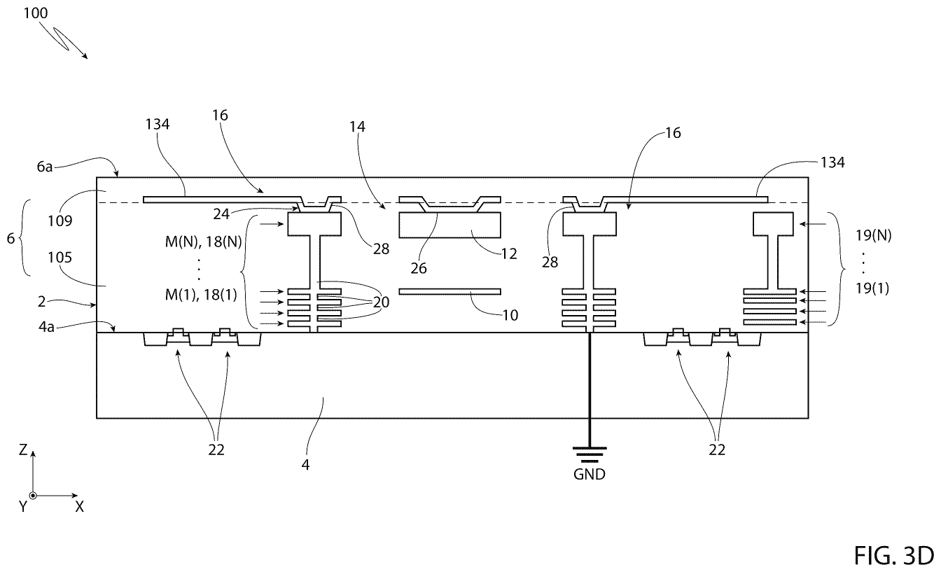

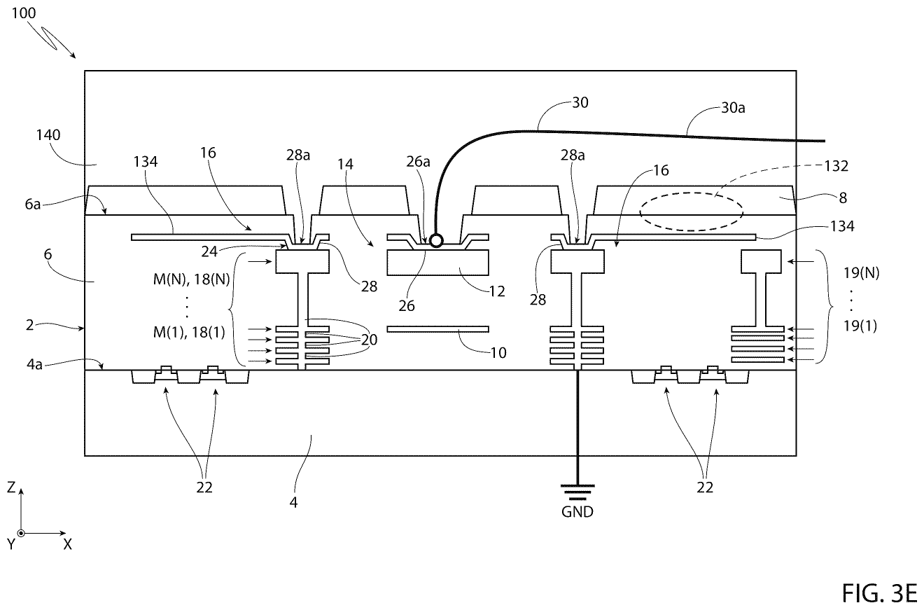

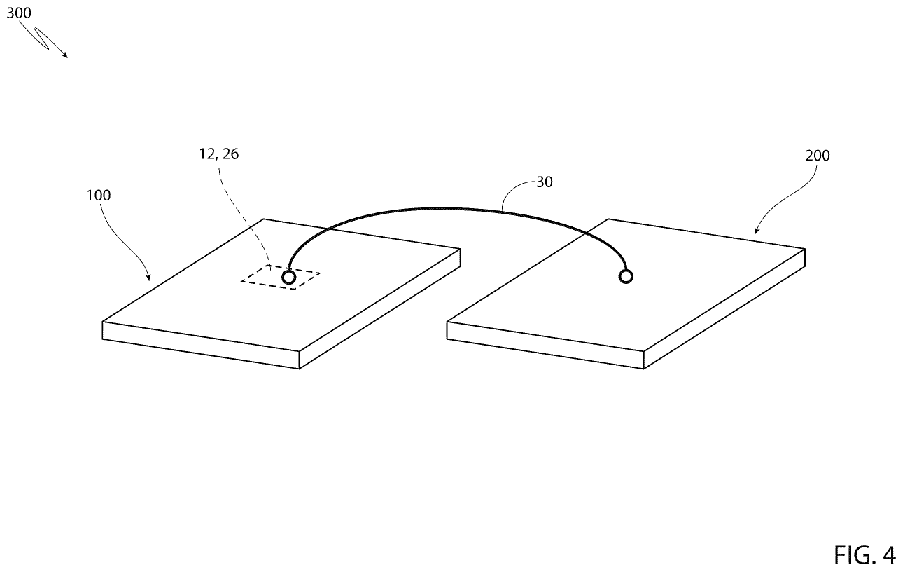

With reference to FIGS. 3A-3E, a manufacturing method of the die 100 according to an embodiment is now described, limited to the manufacturing steps relevant to the embodiment and to a portion of the die 100 relevant to the embodiment. FIGS. 3A-3E schematically represent the die 100 in lateral section on the xz plane.

With reference to FIG. 3A, the substrate 4 including the semiconductor device 22 is provided. On the substrate 4 there are formed, in a manner known per se, the guard ring 16, the first metal plate 10 and the second metal plate 12 of the capacitor 14, the further metal layers 19(1)-19(N), and a first dielectric portion 105 of the dielectric layer 6. The first dielectric portion 105 completely covers the guard ring 16 and the capacitor 14, and has a first face 105a and a second face 105b opposite to each other along the z axis. The second face 105b directly faces (in particular, in direct physical contact with) the surface 4a of the substrate 4.

With reference to FIG. 3B, a masked etching is performed (for example through lithography and “Reactive Ions Etching” (RIE) steps) of the first face 105a of the first dielectric portion 105, opening trenches 107 at the guard ring 116 and the second metal plate 12. The trenches 107 expose surfaces 116a and 112a respectively of the top metal layer 18(N) belonging to the guard ring 16 and of the second metal plate 12.

With reference to FIG. 3C, the capping layer 24 is deposited on the first face 105a and on the surfaces 116a and 112a (for example through physical vapor deposition (PVD) or through sputtering). The patterning of the capping layer 24 is then performed (for example through successive lithography and etching steps) to form the portions 26 and 28, and the metal screen 134.

With reference to FIG. 3D, a deposition step is performed (for example through plasma-assisted chemical vapor deposition (CVD)) of a second dielectric portion 109, above the capping layer 24 and the first dielectric portion 105. The first dielectric portion 105 and the second dielectric portion 109 form, as a whole, the dielectric layer 6.

With reference to FIG. 3E, a deposition step of the passivation layer 8 is performed (for example through Chemical Vapor Deposition (CVD) or Physical Vapor Deposition (PVD) or coat spinning or other process, followed by one or more masked etching steps (for example through successive lithography and chemical etching steps) of the passivation layer 8 and the dielectric layer 6 to expose respective portions of the surfaces 26a and 28a of the respective portions 26 and 28. A coupling step is then performed (for example by soldering or wire bonding) of the bonding wire 30, physically and electrically coupling one end of the bonding wire 30 to the surface 26a of the capping portion 26, thus obtaining the die 100 of FIG. 2.

Optionally, the die 100 may be packaged completely or partly in a passivating layer of molding compound 140, adapted to protect the die 100 and the bonding wire 30, preventing external contaminations and attenuating mechanical stresses that might cause the detachment of the bonding wire 30. Electrical contact regions are formed through the passivating layer of molding compound for biasing the die 100, in a manner known per se.

Finally, it is clear that modifications and variations may be made to what has been described and illustrated here without thereby departing from the scope of the present invention, as defined in the attached claims.

1. A semiconductor die, comprising:
a semiconductor substrate having a first surface;
a dielectric layer extending on the first surface and having a second surface opposite to the first surface along an axis;
a high-voltage circuit module extending on the semiconductor substrate at least partly into the dielectric layer;
a metal guard ring extending into the dielectric layer, completely surrounding the high-voltage circuit module, and configured to be electrically coupled, in use, to a reference potential;
at least one electronic device extending at the first surface externally to the metal guard ring;
a metal capping layer including: a first portion extending over the high-voltage module and in electrical contact with the high-voltage module; and a second portion, electrically isolated from the first portion, extending over the metal guard ring and in electrical contact with the metal guard ring;
a bonding wire electrically coupled to the first portion of the metal capping layer, and extending over the dielectric layer at said electronic device;
a plurality of metal levels in the dielectric layer, each metal level including at least one respective first metal path for routing electrical signals and at least one respective second metal path forming a portion of the metal guard ring; and
a metal screen above the guard ring, interposed between the bonding wire and the electronic device, in physical and electrical continuity with the second portion of the metal capping layer.

2. The semiconductor die according to claim 1, wherein the metal screen and the second portion of the metal capping layer are made of a same metal material.

3. The semiconductor die according to claim 1:
wherein a top metal level among said plurality of metal levels is located at a greater distance from the first surface of the substrate along said axis; and
wherein the second portion of the metal capping layer is in electrical contact with the second metal path of the top metal level.

4. The semiconductor die according to claim 3:
wherein the top metal level further accommodates a first metal portion of the high-voltage module; and
wherein the first portion of the metal capping layer is in electrical contact with the first metal portion of the high-voltage module.

5. The semiconductor die according to claim 3, wherein the portion of metal screen extends at a distance from the first surface of the substrate along said axis greater than the corresponding distance of the top metal level.

6. The semiconductor die according to claim 1, wherein the first and second portions of the metal capping layer and the metal screen are made of one of: aluminum, or an alloy including aluminum, or an aluminum-copper alloy.

7. The semiconductor die according to claim 1, wherein each first and second metal path is made of, or includes, copper.

8. The semiconductor die according to claim 1, wherein the metal screen completely surrounds the metal guard ring.

9. The semiconductor die according to claim 1, wherein the first and second portions of the metal capping layer and the metal screen have a respective thickness, along said axis, comprised between 0.5 μm and 3 μm.

10. A system, comprising:
the semiconductor die according to claim 1; and
a further semiconductor die,
wherein said bonding wire connects the further semiconductor die to the first portion of the semiconductor die.

11. An electronic device, comprising:
a semiconductor substrate having a first surface comprising an active component; and
a solid body extending on the first surface of the semiconductor substrate, the solid body comprising:
a dielectric layer,
a capacitor in the dielectric layer, wherein the capacitor comprises a first metal plate at a first height with respect to the semiconductor substrate and a second metal plate at a second height smaller than the first height with respect to the semiconductor substrate;
a metal guard ring into the dielectric layer, the metal guard ring completely surrounding the capacitor; and
a metal capping layer including a first portion extending over the capacitor and in electrical contact with the capacitor; and a second portion, electrically isolated from the first portion, extending over the metal guard ring and in electrical contact with the metal guard ring;
wherein the at least one active component extends, at the first surface of the semiconductor substrate, on opposite side of the metal guard ring with respect to the capacitor, and
wherein the second portion of the metal capping layer develops beyond a footprint of the metal guard ring to cover the active component.

12. The electronic device according to claim 11, wherein the solid body further comprises a plurality of metal levels in the dielectric layer, each metal level including at least one respective first metal path for routing electrical signals and at least one respective second metal path forming a portion of the metal guard ring.

13. The electronic device according to claim 12, wherein a top metal level of the plurality of metal levels comprises a top first metal path and a top second metal path, wherein the top metal level is the furthest metal level from the semiconductor substrate among the plurality of metal levels, and wherein the second portion of the metal capping layer is in electrical contact with the top second metal path.

14. The electronic device according to claim 13, wherein the top metal level further accommodates the first metal plate of the capacitor, wherein the first portion of the metal capping layer is in electrical contact with the first metal portion of the capacitor.

15. The electronic device according to claim 13, wherein a distance, along a vertical direction, between the active component and the second portion of the metal capping layer is greater than a respective distance, along the vertical direction, between the active component and the top metal level.

16. The electronic device according to claim 11, wherein the first and the second portions of the metal capping layer are of aluminum, or an alloy including aluminum, or an aluminum-copper alloy.

17. The electronic device according to claim 13, wherein each first metal path and each second metal path is made of, or includes, copper.

18. The electronic device according to claim 11, wherein the second portion of the metal capping layer completely surrounds the metal guard ring.

19. The electronic device according to claim 11, wherein the first and the second portions of the metal capping layer have a respective thickness comprised between 0.5 μm and 3 μm.

20. A system comprising:
the electronic device according to claim 11;
a further electronic device; and
a bonding wire connecting the further electronic device to the electronic device at the first portion of the metal capping layer.
